(19) United States
(12) Patent Application Publication
(10) Pub. No.: US 2025/0125295 A1
(43) Pub. Date: Apr. 17, 2025

(54) SEMICONDUCTOR PACKAGE AND METHOD FOR MAKING THE SAME

(71) Applicant: JCET STATS ChipPAC Korea Limited, Incheon (KR)

(72) Inventors: SeungHyun LEE, Incheon (KR); SangJun PARK, Incheon (KR); NamGu KIM, Incheon (KR); GyeongMin KIM, Incheon (KR); JiYeon KIM, Incheon (KR); SoYeong LEE, Incheon (KR)

(21) Appl. No.: 18/829,324

(22) Filed: Sep. 10, 2024

(30) Foreign Application Priority Data
Oct. 11, 2023 (CN) 202311311106.9

(51) Int. Cl. H01L 23/00; H01L 21/56; H01L 23/31; H01L 23/498; H01L 23/552

(52) U.S. Cl. CPC H01L 24/16; H01L 21/56; H01L 23/3121; H01L 23/3135; H01L 23/49838; H01L 23/552; H01L 24/11; H01L 24/14; H01L 2224/11602; H01L 2224/11849; H01L 2224/1403; H01L 2224/16225; H01L 2924/1815

(57) ABSTRACT

A semiconductor package and a method for making the same are provided. The method includes: providing a package substrate having a first surface and a second surface opposite to the first surface; mounting a plurality of conductive blocks onto the first surface of the package substrate; forming at least one conductive bump on each of the conductive blocks; forming a first encapsulant on the first surface of the package substrate to encapsulate the conductive blocks and the conductive bump on each of the conductive blocks; and grinding the first encapsulant to remove an upper portion of the first encapsulant and an upper portion of the conductive bump on each of the conductive blocks, such that an exposed surface of the conductive bump on each of the conductive blocks is at a same height relative to the first surface of the package substrate.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. In recent years, semiconductor packages are fabricated into smaller sizes to bring about higher density of electronic components. Typically, the semiconductor packages may include key functional modules, such as semiconductor chips and interconnection structures. However, it is noted that certain interconnection formation processes, such as stacking multiple layers of solder balls in a single through hole for higher interconnect structures, may be complicated and not cost effective. Also, such complicated process may adversely affect the yield of the semiconductor packages incorporating such interconnection structures.

Therefore, a need exists for a method for forming a semiconductor package with a simple process and an improved yield.

### SUMMARY OF THE INVENTION

An objective of the present application is to provide a method for forming a semiconductor package with a simple process and an improved yield.

According to an aspect of the present application, a method for forming a semiconductor package is provided. The method may include: providing a package substrate having a first surface and a second surface opposite to the first surface; mounting a plurality of conductive blocks onto the first surface of the package substrate; forming at least one conductive bump on each of the conductive blocks; forming a first encapsulant on the first surface of the package substrate to encapsulate the conductive blocks and the conductive bump on each of the conductive blocks; and grinding the first encapsulant to remove an upper portion of the first encapsulant and an upper portion of the conductive bump on each of the conductive blocks, such that an exposed surface of the conductive bump on each of the conductive blocks is at a same height relative to the first surface of the package substrate.

According to another aspect of the present application, a semiconductor package is provided. The semiconductor package may be formed using the method above.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view of a conventional semiconductor package.

FIG. 1B is an enlarge view of a portion of the semiconductor package shown in FIG. 1A.

FIGS. 2A to 2J are cross-sectional views illustrating various steps of a method for making a semiconductor package according to an embodiment of the present application.

FIG. 3 is a scanning electron microscope (SEM) image of the conductive block shown in FIG. 2C.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, an approach to form higher interconnection structures in a semiconductor package such as in a mold cap of such semiconductor package is stacking multiple layers of solder balls in a single through hole. However, such approach may be complicated in process. As an alternative approach, preformed conductive blocks such as e-bar blocks, each having one or more conductive pillars built therein, may be mounted in a through hole or cavity on a package substrate to form a thicker interconnection structure.

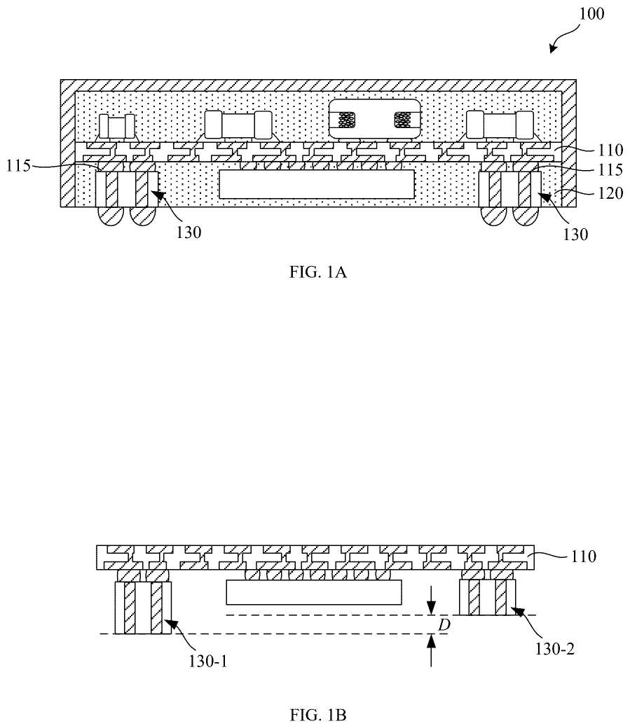

For example, FIG. 1A illustrates a semiconductor package 100, in which preformed conductive blocks 130 are formed on a package substrate 110 to couple electronic components in the semiconductor package 100 to solder bumps. However, the inventors of the present application noticed that the semiconductor package 100 incorporating the conductive blocks 110 has a relatively lower yield and is low in reliability. After an investigation of samples of the semiconductor package 100, the inventors have identified that there may be a significant height difference between the two or more conductive blocks 130 on the package substrate 110, due to a difference in the size and height of solder bumps 115 that mount the conductive blocks 130 onto the package substrate 110. For example, FIG. 1B illustrates an enlarge view of a portion of the semiconductor package 100 shown in FIG. 1A, and an encapsulant 120 is omitted to show the two conductive blocks 130 more clearly. As can be seen, there is a significant height difference D between the two conductive blocks 130-1 and 130-2 shown in FIG. 1B. Consequently, when other electronic components or circuit boards are mounted on the two conductive blocks 130-1 and 130-2, the height difference D may lead to a tilted installation or even an open circuit, which reduces the reliability of the semiconductor package 100.

To address at least one of the above problems, a new method for forming a semiconductor package is provided in an aspect of the present application. In this method, additional conductive bumps are formed on the conductive blocks, and then the conductive bumps are grinded to remove their upper portions, such that top surfaces of the conductive bumps can be at a same height relative to the package substrate. In other words, height differences between the conductive bumps can be introduced during the grinding process to compensate for the height differences between the conductive blocks. Therefore, the yield and reliability of the semiconductor package can be improved.

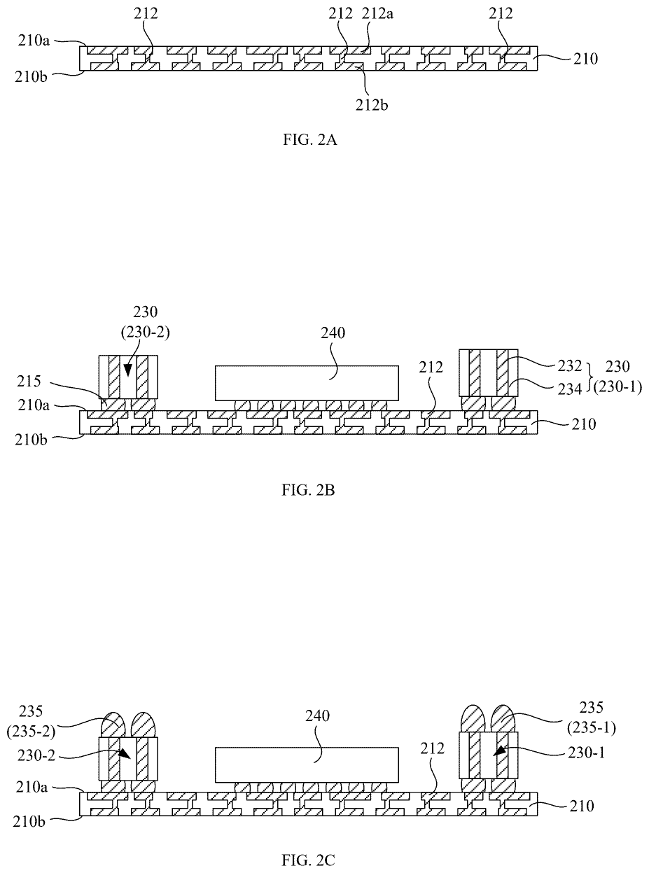

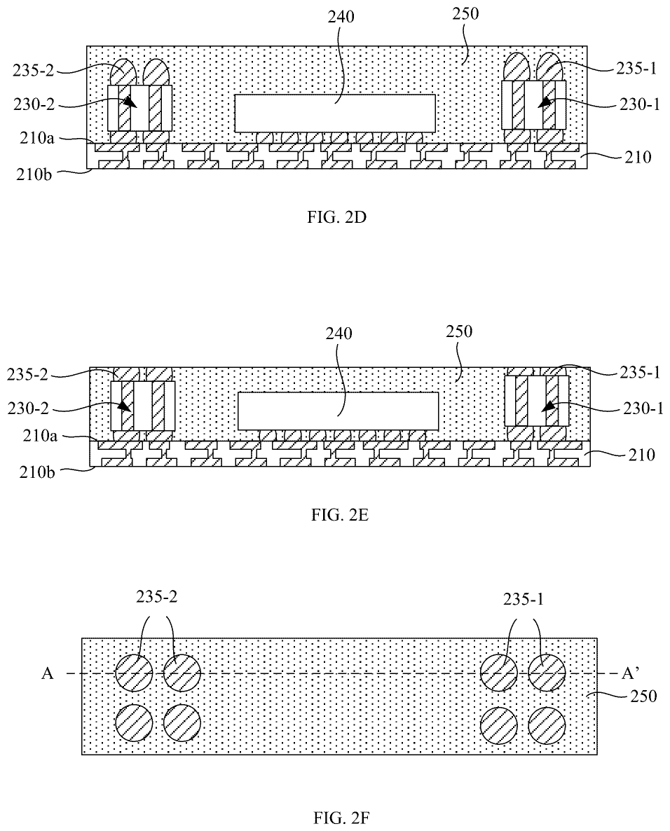

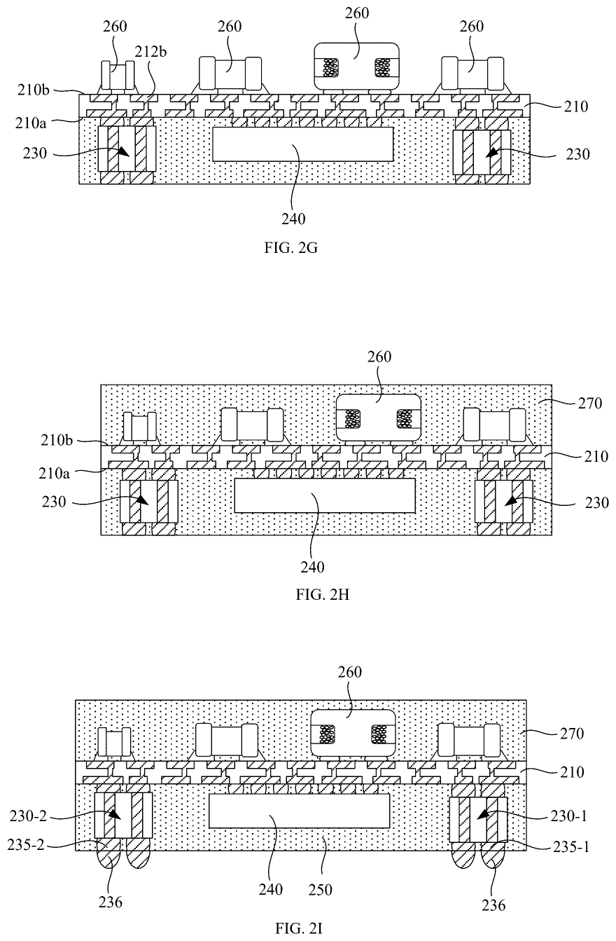

Referring to FIGS. 2A to 2J, various steps of a method for forming a semiconductor package are illustrated according to an embodiment of the present application. In the following, the method will be described with reference to FIGS. 2A to 2J in more details.

Referring to FIG. 2A, a package substrate 210 is provided. The package substrate 210 has a first surface 210a and a second surface 210b opposite to the first surface 210a, and a plurality of interconnection structures 212 are formed in the package substrate 210.

Specifically, the package substrate 210 can provide support and connectivity for electronic components and devices mounted thereon. By way of example, the package substrate 210 may include a printed circuit board (PCB), a carrier substrate, a semiconductor substrate with electrical interconnections, or a ceramic substrate. However, the package substrate 210 is not to be limited to these examples. In other examples, the package substrate 210 may include a laminate interposer, a strip interposer, a leadframe, or other suitable substrates. To enhance manufacturing throughput, the package substrate 210 may include a plurality of predefined substrate units arranged in a strip manner, thereby allowing some manufacturing processes to be performed on all the substrate units in parallel.

The interconnection structures 212 can provide connectivity for electronic components mounted on the package substrate 210. The interconnection structures 212 may define pads, traces and plugs through which electrical signals or voltages can be distributed horizontally and vertically across the package substrate 210. For example, as shown in FIG. 2A, some of the interconnection structures 212 may provide a plurality of first contact pads 212a on the first surface 210a, and a plurality of second contact pads 212b on the second surface 210b.

Referring to FIG. 2B, a plurality of conductive blocks 230 are mounted onto the first surface 210a of the package substrate 210.

In some embodiments, a solder material may be deposited onto the first contact pads 212a on the first surface 210a of the package substrate 210 to form a plurality of solder bumps 215 on the first contact pads 212a. For example, the solder material may include eutectic Sn/Pb, high-lead solder, lead-free solder, or other suitable materials.

Next, a plurality of conductive blocks 230 are placed on the first surface 210a of the package substrate 210 and in contact with some of the solder bumps 215, and the solder bumps 215 may be reflowed to mount the conductive blocks 230 onto the first surface 210a of the package substrate 210 via the solder bumps 215, thus forming electrical connection between the interconnect structures 212 and the conductive blocks 230. Similarly, at least one first electronic component 240 are also mounted onto the first surface 210a of the package substrate 210 via some of the solder bumps 215, thus forming electrical connection between the interconnect structures 212 and the first electronic component 240. In some embodiments, the first electronic component 240 may be semiconductor chips or smaller semiconductor packages. In some embodiments, the conductive blocks 230 are thicker than the first electronic component 240. In other words, a top surface the first electronic component 240 may be lower than top surfaces of the conductive blocks 230. In this way, the semiconductor package may be electrically connected with other external electronic devices via the conductive blocks 230 while, at the same time, keeping the first electronic component 240 isolated from other devices. In some embodiments, the conductive blocks 230 and the first electronic component 240 can be attached onto the first surface 210a of the package substrate 210 simultaneously, while in some other embodiments, the conductive blocks 230 may be attached onto the first surface 210a of the package substrate 210 before or after the first electronic component 240 is attached.

In some embodiments, the conductive blocks 230 may be e-bar blocks that include built in conductive pillars such as copper pillars and an insulative base material separating the copper pillars from each other. For example, as shown in FIG. 2B, each e-bar block 230 includes two conductive pillars 232 which are surrounded by a dielectric layer 234 such as an insulative polymeric material or composite. To be more specific, bottom surfaces of the conductive pillars 232 are exposed from a bottom surface of the dielectric layer 234 for contacting the solder bumps 215. Similarly, top surfaces of the conductive pillars 232 are exposed from a top surface of the dielectric layer 234 for electrical contact purpose, for example, with an external device. In some embodiments, the conductive pillars 232 in some conductive blocks 230 are electrically connected with each other. In some other embodiments, the conductive pillars 232 in some conductive blocks 230 are not electrically connected with each other but electrically isolated from each other for separate electrical paths. It could be understood that the number of the conductive pillars 232 included in each conductive block 230 may vary according to actual needs of the semiconductor package.

In the example shown in FIG. 2B, the plurality of conductive blocks 230 includes a first conductive block 230-1 mounted on the right portion of the package substrate 210 and a second conductive block 230-2 mounted on the left portion of the package substrate 210. As mentioned before, the conductive blocks 230 at different positions on the package substrate 210 may have different heights due to, for example, the unevenness of the first surface 210a of the package substrate 210, the nonuniformity of the forming process of the solder bumps 215 and/or the inconformity of the attaching process of the conductive blocks 230 onto the package substrate 210. For example, the heights of the solder bumps 215 under the first conductive block 230-1 may be different from the heights of the solder bumps 215 under the second conductive block 230-2, rendering a height difference between the top surfaces of the first conductive block 230-1 and the second conductive block 230-2. Specifically, the top surface of the first conductive block 230-1 is higher than the top surface of the second conductive block 230-2, as shown in FIG. 2B.

Referring to FIG. 2C, at least one conductive bump 235 is formed on each of the plurality of conductive blocks 230.

In some embodiments, the conductive bump 235 may be a solder bump. For example, a solder material may be printed or deposited onto the top surfaces of the conductive blocks 230. Then, the solder material may be reflowed by heating the material above its melting point to form the solder bumps 235.

In the example shown in FIG. 2C, two first solder bumps 235-1 are formed on the first conductive block 230-1, and two second solder bumps 235-2 are formed on the second conductive block 230-2. As the top surface of the first conductive block 230-1 is higher than the top surface of the second conductive block 230-2, top surfaces of the first solder bumps 235-1 may be higher than top surfaces of the second solder bumps 235-2. As shown in FIG. 2C, each of the two first solder bumps 235-1 and the second solder bumps 235-2 may have an oval cross-section. In other examples, each of the solder bumps may have a semicircular cross-section, etc.

Referring to FIG. 2D, a first encapsulant 250 is formed on the first surface 210a of the package substrate 210 to encapsulate the conductive blocks 230, the conductive bumps 235 on the conductive blocks 230, and the first electronic component 240.

In some embodiments, a molding material is formed on the first surface 210a of the package substrate 210 to form the first encapsulant 250 that encapsulates the conductive blocks 230, the conductive bumps 235 on the conductive blocks 230, and the first electronic component 240. The molding material may include epoxy resin, epoxy resin with filler, epoxy acrylate with filler, or polymer with proper filler, but the scope of this application is not limited thereto. In some embodiments, the first encapsulant 250 may be formed by using compressive molding, transfer molding, liquid encapsulant molding, or other suitable molding processes.

Referring to both FIG. 2D and FIG. 2E, the first encapsulant 250 is grinded to remove an upper portion of the first encapsulant 250 and an upper portion of the conductive bump 235 on each of the conductive blocks 230, such that an exposed surface of the conductive bump 235 on each of the conductive blocks 230 is at a same height relative to the first surface 210a of the package substrate 210.

In some embodiments, a grinder may be used to grind the top surface of the first encapsulant 250, until an upper portion of the first encapsulant 250 and an upper portion of the conductive bump 235 on each of the conductive blocks 230 are removed. As the grinding process can also planarize the top surface of the first encapsulant 250, an exposed surface of the conductive bump 235 on each of the conductive blocks 230 can be substantially flush or coplanar with each other.

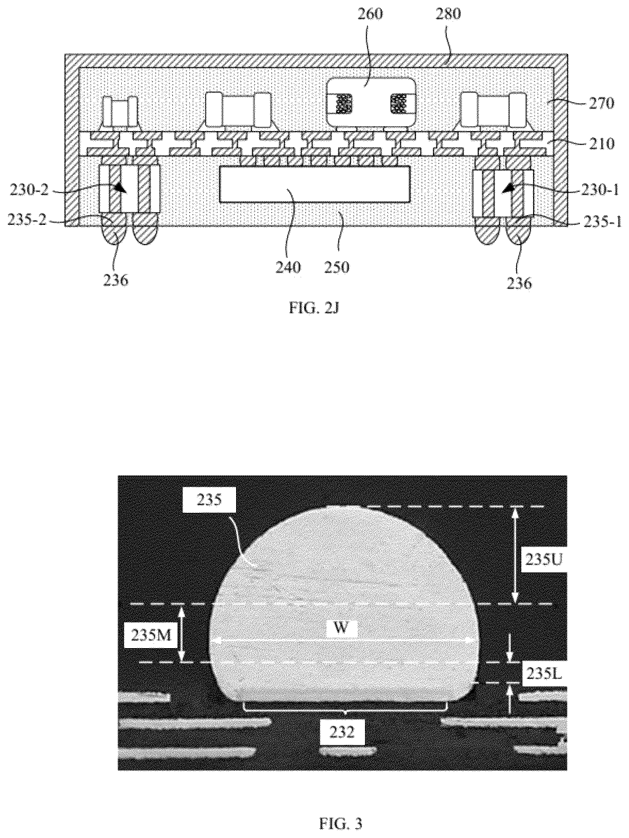

As shown in FIG. 2E, after the grinding process, both an upper portion of the first solder bump 235-1 and an upper portion of the second solder bump 235-2 are removed, but the first electronic component 240 is still covered by the first encapsulant 250. As the top surfaces of the first solder bumps 235-1 are higher than the top surfaces of the second solder bumps 235-2, the removed portions of the first solder bumps 235-1 may be thicker than the removed portions of the second solder bumps 235-2. Referring to FIG. 2F, a top view of the structure shown in FIG. 2E is illustrated, and FIG. 2E is a cross-sectional view of the structure along a section line A-A′ shown in FIG. 2F. As shown in FIG. 2F, the exposed surfaces of the first solder bump 235-1 and the second solder bump 235-2 may have substantially the same size and/or shape. More details about the configuration of the solder bumps will be described at last with reference to FIG. 3.

Referring to FIG. 2G, the package substrate 210 is flipped, and at least one second electronic component 260 is mounted onto the second surface 210b of the package substrate 210.

In some embodiments, a solder material may be deposited onto the second contact pads 212b on the second surface 210b of the package substrate 210 to form a plurality of solder bumps. For example, the solder material may include eutectic Sn/Pb, high-lead solder, lead-free solder, or other suitable materials. Next, at least one second electronic component 260 are placed on the second surface 210b of the package substrate 210 and in contact with the solder bumps, and the solder bumps may be reflowed to mount the second electronic component 260 onto the second surface 210b of the package substrate 210 via the solder bumps. In this way, the first electronic component 240 mounted on the first surface 210a of the package substrate 210, the second electronic component 260 mounted on the second surface 210b of the package substrate 210, and the conductive blocks 230 can be electrically connected with one another, forming an integrated package. The integrated package may be further connected with external circuits via the conductive blocks 230.

In some embodiments, the second electronic component 260 may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), a discrete device, etc. In some embodiments, the second electronic component 260 may be small IC chips that contain different well-defined subsets of functionalities, and allow to integrate a variety of different architectures, different process nodes, and even dedicated silicon blocks or intellectual property (IP) blocks from different foundries into a single package. In some other embodiments, it can be appreciated that the second electronic component 260 may be arranged and sized according to actual needs of the semiconductor package.

Referring to FIG. 2H, a second encapsulant 270 is formed on the second surface 210b of the package substrate 210 to encapsulate the second electronic component 260.

In some embodiments, a molding material is formed on the second surface 210b of the package substrate 210 to form the second encapsulant 270 that encapsulates the second electronic component 260. The molding material may include epoxy resin, epoxy resin with filler, epoxy acrylate with filler, or polymer with proper filler, but the scope of this application is not limited thereto. In some embodiments, the second encapsulant 270 may be formed by using compressive molding, transfer molding, liquid encapsulant molding, or other suitable molding processes. Consequently, a double side molded package is formed with the electronic components attached and packaged on both the first surface 210a and the second surface 210b of the package substrate 210.

Referring to FIG. 2I, a solder bump 236 is formed on the exposed surface of the conductive bump 235 on each of the conductive blocks 230.

In some embodiments, a solder material may be printed or deposited onto the exposed surfaces of the first solder bump 235-1 and second solder bump 235-2, and then the solder material may be reflowed by heating the material above its melting point to form the solder bumps 236. The solder material may include eutectic Sn/Pb, high-lead solder, lead-free solder, or other suitable materials. In some other embodiments, the solder bumps 236 may be compression bonded or thermocompression bonded onto the exposed surfaces of the first solder bump 235-1 and second solder bump 235-2. The solder bumps 236 shown in FIG. 2I may represent one type of external conductive bumps that can be formed on the exposed surfaces of the first solder bump 235-1 and second solder bump 235-2. In other examples, the external conductive bumps may be a stud bump, a micro bump, or other electrical interconnects.

At last, referring to FIG. 2J, an electromagnetic interference (EMI) shield 280 may be formed to cover top and lateral surfaces of the second encapsulant 270, and lateral surfaces of the package substrate 210 and the first encapsulant 250.

The EMI shield 280 may be formed from copper, aluminum, iron, or any other suitable material for EMI shielding. In some embodiments, the EMI shield 280 may be formed by spray coating, plating, sputtering, or any other suitable metal deposition process. The EMI shield 280 may follow the shapes and/or contours of the second encapsulant 270, and the lateral surfaces of the package substrate 210 and the first encapsulant 250.

In some embodiments, when the package substrate 210 includes a plurality of predefined substrate units arranged in a strip manner, a singulation process may be performed to singulate each individual package from the package strip along singulation channels before the step of forming the EMI shield 280. For example, the package strip can be singulated into individual packages through the singulation channels using a saw blade. In some other examples, a laser cutting tool can also be used to singulate the package strip.

While various processes for forming the semiconductor package are illustrated in conjunction with FIGS. 2A-2J, it will be appreciated by those skilled in the art that modifications and adaptations to the processes may be made without departing from the scope of the present invention.

FIG. 3 illustrates a scanning electron microscope (SEM) image of a portion of a conductive block (for example, the conductive pillars 232 of the conductive block 230 shown in FIG. 2B) and a conductive bump (for example, the solder bump or ball 235 formed in FIG. 2C).

The inventors of the present application found that when a diameter of the solder ball 235 is larger than a width of the top surface of the conductive pillars 232 which is exposed from a solder resist opening (SRO) of the dielectric layer 234 of the conductive block 230, the solder ball 235 may have an oval cross-section after the reflow process. Especially, as shown in FIG. 3, the solder ball 235 may have an upper portion 235U, a lower portion 235L and a middle portion 235M, and the width “W” of the solder ball 235 may vary little in the middle portion 235M. Taking the embodiment shown in FIG. 2D as an example, both the first solder bump 235-1 and the second solder bump 235-2 have an oval cross-section after the reflow process, and there may be a height difference between the first solder bump 235-1 and the second solder bump 235-2 because of the height variance between the first conductive block 230-1 and the second conductive block 230-2. Referring to FIG. 2E and FIG. 3, the grinding process may be controlled to stop at the middle portions 235M of the first solder bump 235-1 and the second solder bump 235-2. For example, the first solder bump 235-1 is grinded until the lower part of the middle portion 235M, while the second solder bump 235-2 is grinded until the upper part of the middle portion 235M. As the width “W” of the first solder bump 235-1 and the second solder bump 235-2 vary little in the middle portion 235M, the exposed areas of the first solder bump 235-1 and the second solder bump 235-2 are substantially the same with each other, as shown in FIG. 2E.

On the other hand, when a diameter of the solder ball 235 is smaller than the width of the top surface of the conductive pillars 232, the solder ball 235 may have an semicircular cross-section after the reflow process, and the width of the solder ball 235 may vary greatly in its middle portion 235M. Thus, it is hard to ensure that the exposed areas of the first solder bump 235-1 and the second solder bump 235-2 shown in FIG. 2F are the same after the grinding process, reducing the reliability of the semiconductor package to be formed.

Thus, in the present application, it is preferred that the diameter of the solder ball 235 is larger than the width of the top surface of the conductive pillars 232. For example, a solder ball 235 having a 280 μm diameter may be formed on a conductive pillar 232 having a 210 μm width in the step shown in FIG. 2C.

According to another aspect of the present application, a semiconductor package made by the methods described above is provided. The details of the semiconductor package may refer to the methods described above, and are not elaborated herein.

The discussion herein included numerous illustrative figures that showed various portions of a semiconductor package and a method for making the same. For illustrative clarity, such figures did not show all aspects of each example package. Any of the example packages and/or methods provided herein may share any or all characteristics with any or all other devices and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a package substrate having a first surface and a second surface opposite to the first surface;
mounting a plurality of conductive blocks onto the first surface of the package substrate;
forming at least one conductive bump on each of the conductive blocks;
forming a first encapsulant on the first surface of the package substrate to encapsulate the conductive blocks and the conductive bump on each of the conductive blocks; and
grinding the first encapsulant to remove an upper portion of the first encapsulant and an upper portion of the conductive bump on each of the conductive blocks, such that an exposed surface of the conductive bump on each of the conductive blocks is at a same height relative to the first surface of the package substrate.

2. The method of claim 1, further comprising:
forming a solder bump on the exposed surface of the conductive bump on each of the conductive blocks.

3. The method of claim 1, wherein the package substrate comprises a plurality of conductive pads formed on the first surface of the package substrate, and mounting the plurality of conductive blocks onto the first surface of the package substrate comprises:
depositing a solder material onto the plurality of conductive pads formed on the first surface of the package substrate;
placing the plurality of conductive blocks on the first surface of the package substrate and in contact with the solder material; and
reflowing the solder material to mount the plurality of conductive blocks onto the first surface of the package substrate.

4. The method of claim 1, wherein the plurality of conductive blocks comprises a first conductive block and a second conductive block, and a top surface of the first conductive block is higher than a top surface of the second conductive block.

5. The method of claim 4, wherein forming at least one conductive bump on each of the conductive blocks comprises:
forming a first conductive bump on the first conductive block; and
forming a second conductive bump on the second conductive block, wherein a top surface of the first conductive bump is higher than a top surface of the second conductive bump.

6. The method of claim 1, wherein before forming the first encapsulant on the first surface of the package substrate, the method further comprises:
mounting at least one first electronic component onto the first surface of the package substrate.

7. The method of claim 6, wherein a top surface of the first electronic component is lower than top surfaces of the plurality of conductive blocks.

8. The method of claim 1, wherein after grinding the first encapsulant, the method further comprises:
mounting at least one second electronic component onto the second surface of the package substrate.

9. The method of claim 8, further comprising:
forming a second encapsulant on the second surface of the package substrate to encapsulate the second electronic component.

10. The method of claim 9, further comprising:
forming an electromagnetic interference (EMI) shield to cover top and lateral surfaces of the second encapsulant, and lateral surfaces of the package substrate and the first encapsulant.

11. The method of claim 1, wherein the conductive bump comprises a solder bump.

12. The method of claim 1, wherein the plurality of conductive blocks comprises an e-bar block.

13. A semiconductor package, wherein the semiconductor package is formed using the method of claim 1.
